(19) United States
(12) Patent Application Publication
(10) Pub. No.: US 2024/0095126 A1
(43) Pub. Date: Mar. 21, 2024

(54) MICROCONTROLLER AND ELECTRONIC CIRCUIT

(71) Applicant: LAPIS Technology Co., Ltd., Yokohama (JP)

(72) Inventor: Kenichi MORIOKA, Yokohama (JP)

(73) Assignee: LAPIS Technology Co., Ltd., Yokohama (JP)

(21) Appl. No.: 18/469,767

(22) Filed: Sep. 19, 2023

(30) Foreign Application Priority Data
Sep. 21, 2022 (JP) 2022-150550

(51) Int. Cl. G06F 11/14; H03K 17/567

(52) U.S. Cl. CPC G06F 11/1441; H03K 17/567; G06F 2201/805

(57) ABSTRACT

A PWM control circuit is configured to control the operation of an external circuit, and stop operations upon input of an anomaly detection signal from an externally provided anomaly detection circuit. A voltage detection circuit is configured to detect a change in the voltage value of a power source voltage and generate and output a hardware reset signal. A reset circuit outputs a reset signal to reset an entire device if the hardware reset signal from the voltage detection circuit, a software reset signal from a CPU, or the anomaly detection signal becomes active.

### CROSS REFERENCE TO RELATED APPLICATION

This application is based upon and claims the benefit of priority of the prior Japanese Patent Application No. 2022-150550, filed on Sep. 21, 2022, the entire contents of which are incorporated herein by reference.

### TECHNICAL FIELD

The disclosure relates to a microcontroller and an electronic circuit.

### BACKGROUND ART

In general, microcontrollers (or microcontroller units; hereinafter referred to as “MCUs”) have a central processing unit (CPU) and peripheral circuits that together constitute a semiconductor integrated circuit, and are used for controlling the operations of various systems. In some cases, MCUs are used while having connected thereto an external circuit having an insulated-gate bipolar transistor (IGBT). In this case, the MCU has therein a pulse width modulation (PWM) control circuit for controlling the IGBT, and the operations of the IGBT are controlled by the PWM signal outputted from the PWM control circuit.

In a system configured in this manner, there is a possibility that some factor results in an anomalous current flowing to the IGBT. If control is continued while the anomalous current flows in the IGBT, this can result in the IGBT malfunctioning. In order to avoid such a situation, the PWM control circuit is sometimes equipped with an emergency stop function. In this case, if an anomaly detection circuit for detecting an anomalous state in the IGBT is provided and an anomaly detection signal from the anomaly detection circuit is inputted to the PWM control circuit, then the emergency stop function operates when the IGBT is in an anomalous state, operation of the PWM control circuit is stopped, and the output of the PWM signal is stopped.

Japanese Patent Application Laid-Open Publication No. 2013-051547, for example, discloses a circuit configuration including: a gate driver IC with a protection function that transmits an alarm signal to the CPU if it is determined that the current to the IGBT has exceeded a threshold at which the IGBT would be damaged, on the basis of an excessive heat detection signal outputted from a temperature sensor and an overcurrent detection signal outputted from a current sensor; and a CPU that upon receiving the alarm signal interrupts the current flowing to the IGBT by stopping the generation of a gate drive PWM signal.

In some systems, if an anomalous state is detected, then not only is output of the PWM signal stopped, but the resetting of the entire MCU is required. This is because, depending on the anomalous state, there are cases in which the internal state of the MCU cannot be guaranteed to be in a normal state, and resetting the entire MCU is required in order to bring the MCU to a safe state.

In the MCU, resetting is performed over various paths, including not only a hardware reset based on the voltage value of a power source voltage, but also a software reset by the CPU and the like.

In Japanese Patent Application Laid-Open Publication No. 2005-316594, for example, discloses a microcomputer configured such that a reset register is provided to each of a plurality of functional blocks located internally, and the CPU writes data to each reset register, thereby enabling control to individually reset each of the functional blocks.

As described above, if an anomalous state were to occur in the external circuit of the MCU, one method to reset the entire MCU upon detecting the anomalous state is to reset the entire MCU via software. If the power source voltage changes due to the anomalous state, then one method is to reset the entire MCU upon a voltage detection circuit in the MCU detecting a fluctuation in the power source voltage.

### SUMMARY OF THE INVENTION

However, in the state described above, resetting the entire MCU via software by the CPU relies on the fact that the software is in normal operation from when the anomalous state is detected to when the reset is performed. This presents the problem that if the anomalous state results in the operation of the software itself being anomalous, then the entire MCU cannot be reset.

Also, resetting the entire MCU upon detecting an anomaly in the power source voltage using a voltage detection circuit or the like poses the problem that depending on the characteristics of the voltage detection circuit, an anomalous state cannot be detected instantaneously, which prevents the entire MCU from being reset.

An object of the disclosure is to provide a microcontroller and an electronic circuit by which the entire microcontroller can be reset even if, in a configuration in which an internal circuit of the microcontroller is used to operate an external circuit that is external to the microcontroller, an anomalous state occurs in which a software reset by the CPU cannot be executed and the anomaly cannot be detected by the voltage detection circuit.

In order to solve the above problem, a microcontroller according to the disclosure includes:
an internal circuit configured so as to control an operation of an external circuit, and to stop operation and be controlled by a CPU upon input of an anomaly detection signal from outside;
a voltage detection circuit configured so as to detect a change in a voltage value of a power source voltage and generate and output a hardware reset signal; and
a reset circuit that outputs a reset signal for resetting the entire device if any one of the hardware reset signal from the voltage detection circuit, a software reset signal from the CPU, or the anomaly detection signal becomes active.

Also, in order to solve the above problem, an electronic circuit according to the disclosure includes:
a microcontroller including a CPU;
an external circuit provided outside of the microcontroller; and
an anomaly detection circuit configured to detect an anomalous state in the external circuit and generate an anomaly detection signal,
wherein the microcontroller an internal circuit configured so as to control an operation of the external circuit, and to stop operation and be controlled by the CPU upon input of an anomaly detection signal from the anomaly detection circuit; a voltage detection circuit configured so as to detect a change in a voltage value of a power source voltage and generate and output a hardware reset signal; and a reset circuit that outputs a reset signal for resetting the entire device if any one of the hardware reset signal from the voltage detection circuit, a software reset signal from the CPU, or the anomaly detection signal becomes active.

### BRIEF DESCRIPTION OF THE DRAWINGS

FIG. 1 shows a circuit configuration of an electronic circuit including an MCU 100, where the configuration of the disclosure is not adopted.

FIG. 2 shows a circuit configuration of an electronic circuit including an MCU 10 according to an embodiment of the disclosure.

FIG. 3 is a drawing for describing the operational state of the MCU 10 shown in FIG. 2 when an anomaly has occurred in an external circuit 20.

### DETAILED DESCRIPTION OF EMBODIMENTS

According to the disclosure, it is possible to reset the entire microcontroller even if, in a configuration in which an internal circuit of the microcontroller is used to operate an external circuit that is external to the microcontroller, an anomalous state occurs in which a software reset by the CPU cannot be executed and the anomaly cannot be detected by the voltage detection circuit.

Next, an embodiment of the disclosure will be explained in detail with reference to the drawings.

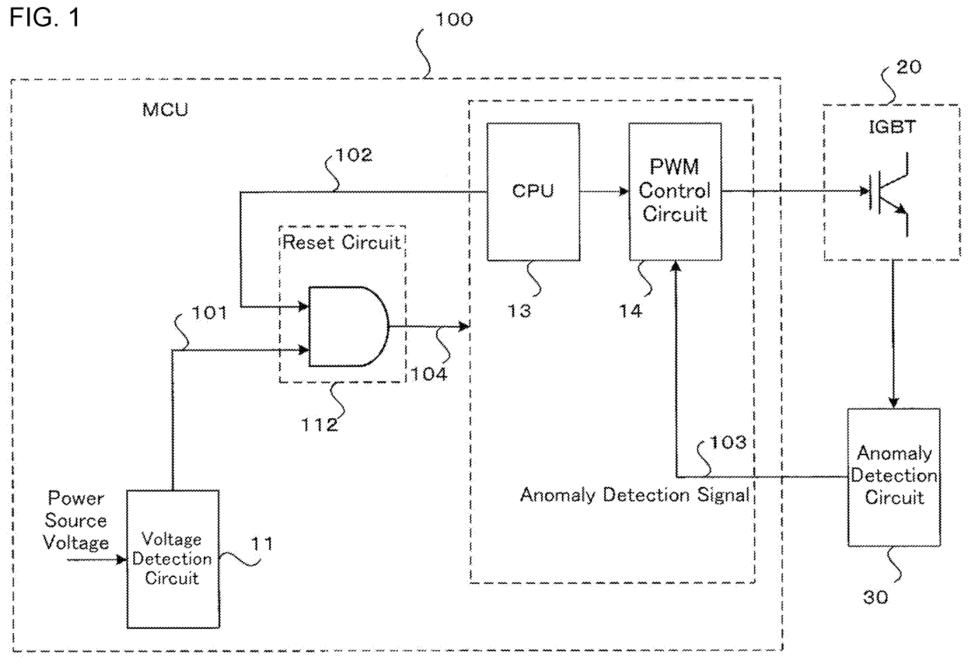

First, prior to explaining the MCU in the present embodiment, a circuit configuration of an electronic circuit that includes a microcontroller 100 (hereinafter abbreviated as “MCU”) that does not adopt the configuration of the disclosure will be described with reference to FIG. 1.

The MCU 100 shown in FIG. 1 includes a voltage detection circuit 11, a reset circuit 112, a CPU 13, and a pulse width modulation (PWM) control circuit 14. Outside of the MCU 100 are provided an external circuit 20 and an anomaly detection circuit 30.

The external circuit 20 is provided outside of the MCU 100 and has an insulated-gate bipolar transistor (IGBT) that is a power semiconductor device.

The anomaly detection circuit 30 is configured to detect an anomalous state in the external circuit 20 and generate an anomaly detection signal 103. Specifically, upon detecting any one of a current anomaly, a voltage anomaly, or a temperature anomaly in the external circuit 20, the anomaly detection circuit 30 generates and outputs the anomaly detection signal 103.

The PWM control circuit 14 is an internal circuit configured so as to control the operation of the external circuit 20 on the basis of an output signal from the CPU 13, and to stop operations and be controlled by the CPU 13 upon input of the anomaly detection signal 103 from the externally provided anomaly detection circuit 30. The PWM control circuit 14 is a circuit for generating a PWM signal for controlling the operation of the IGBT, which is an element of the external circuit 20.

The CPU 13 controls the operation of the MCU 10, generates an output signal for controlling the IGBT of the external circuit 20 to be ON/OFF, and outputs the same to the PWM control circuit 14. Also, the CPU 13 outputs a software reset signal 102 if resetting the MCU 100 via software.

The voltage detection circuit 11 is configured to detect a change in the voltage value of the power source voltage and generate and output a hardware reset signal 101.

In the present embodiment, a case will be described in which the hardware reset signal 101, the software reset signal 102, the anomaly detection signal 103, and the reset signal 104 are all low active signals. Here, low active signals are negative logic signals in which resetting is performed when the signals are at a low level.

The reset circuit 112 outputs the reset signal 104 to reset the entire device if the hardware reset signal 101 from the voltage detection circuit 11 or the software reset signal 102 from the CPU 13 becomes active, that is, reaches a low level.

As a result of the circuit configuration described above, in the MCU 100 shown in FIG. 1, upon the anomaly detection circuit 30 detecting an anomalous state in the external circuit 20 the anomaly detection signal 103 is outputted, and an emergency stop function operates on the PWM control circuit 14, thereby stopping operations. As a result, damage to the IGBT in the external circuit 20 is avoided.

Also, if the power source voltage of the MCU 100 drops, then the voltage detection circuit 11 detects a drop in the power source voltage and outputs the hardware reset signal 101, thereby causing the MCU 100 to stop operations.

Additionally, if the CPU 13 determines that the entire MCU 100 needs to be reset, then the software reset signal 102 is outputted, and thus, the MCU 100 is reset and initialized.

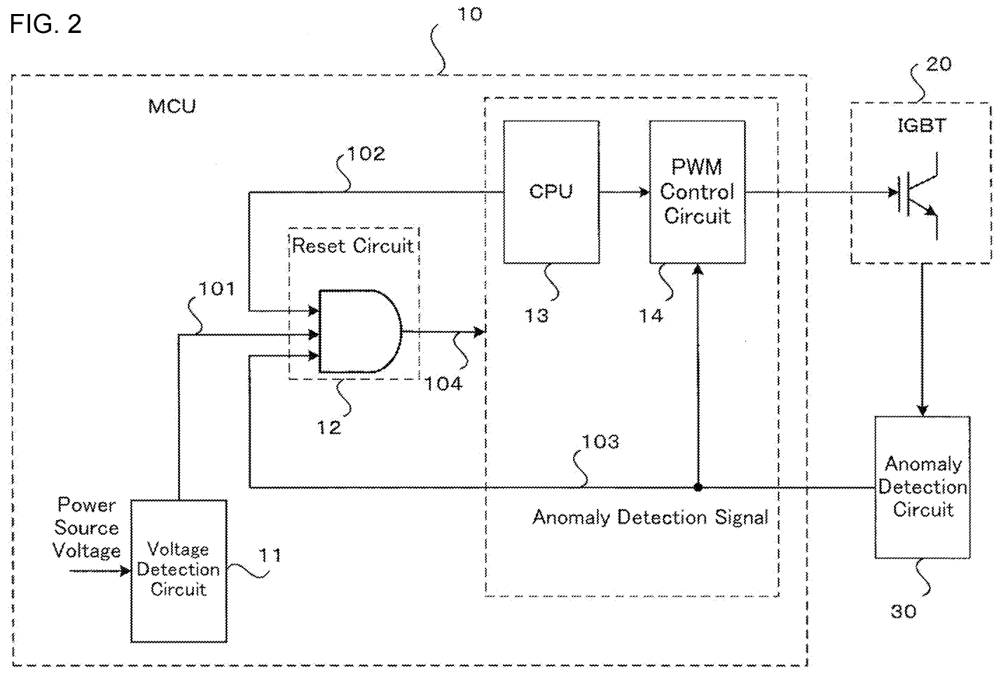

Next, a circuit configuration of an electronic circuit including an MCU 10 according to an embodiment of the disclosure will be described with reference to FIG. 2. The MCU 10 according to the present embodiment, similar to the MCU 100 shown in FIG. 1, has the CPU 13 and peripheral circuits configured together as a semiconductor integrated circuit.

In FIG. 2, components that perform similar operations to the corresponding components shown in FIG. 1 are assigned the same reference characters, and descriptions thereof are omitted.

The MCU 10 of the present embodiment differs from the MCU 100 shown in FIG. 1 by being provided with a reset circuit 12 instead of the reset circuit 112.

The reset circuit 12 of the present embodiment differs from the reset circuit 112 by not only receiving input of the hardware reset signal 101 and the software reset signal 102, but also the anomaly detection signal 103 from the anomaly detection circuit 30.

In the MCU 100 having the circuit configuration shown in FIG. 1 as well, if an anomalous state occurs in the external circuit 20, then the anomaly detection signal 103 outputted from the anomaly detection circuit 30 becomes active, causing the PWM control circuit 14 to stop operations. However, with the system configuration used in the MCU 100, if an anomalous state occurs in the external circuit 20, then a case may occur in which simply stopping the operations of the PWM control circuit 14 is insufficient to restore normal operations, and the entire MCU 100 needs to be reset.

However, in the MCU 100 shown in FIG. 1, if there is an anomaly in the operations of the software by the CPU 13 while an anomaly is occurring in the external circuit 20, then the entire MCU 100 cannot be reset. Also, depending on the characteristics of the voltage detection circuit 11, there are cases in which an anomalous state cannot be detected instantaneously, and if the voltage detection circuit 11 cannot detect the occurrence of an anomalous state when an anomalous state has occurred in the external circuit 20, then the entire MCU 100 cannot be reset.

In the MCU 10 of the present embodiment shown in FIG. 2, it is possible to reset the entire MCU 10 even if an anomalous state occurs in which a software reset by the CPU 13 cannot be executed and the anomaly cannot be detected by the voltage detection circuit 11.

The reset circuit 12 according to the present embodiment outputs the reset signal 104 to reset the entire device if the hardware reset signal 101 from the voltage detection circuit 11, the software reset signal 102 from the CPU 13, or the anomaly detection signal 103 becomes active, that is, reaches a low level.

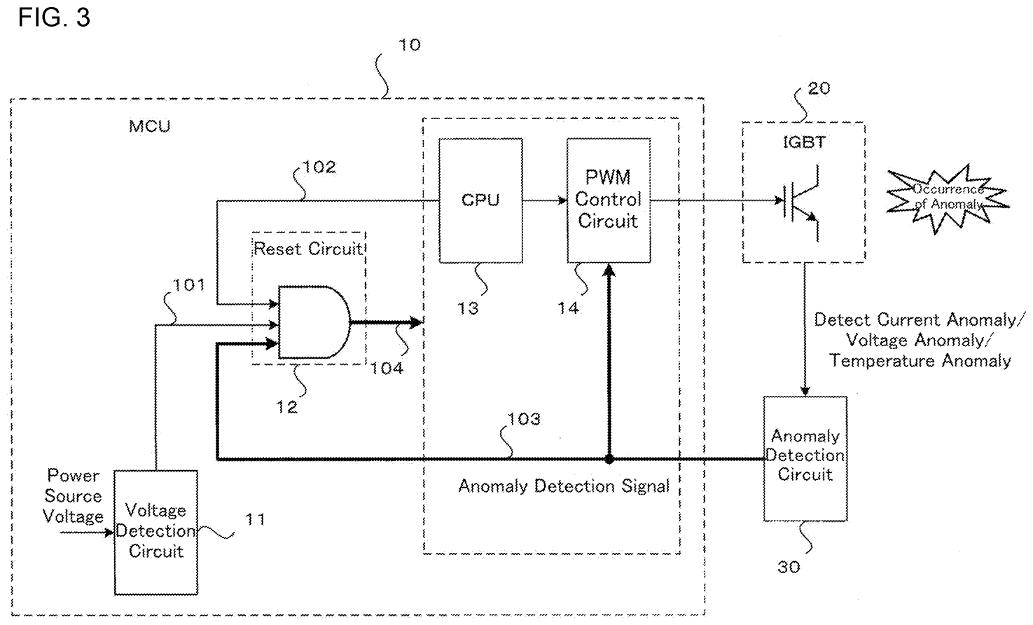

Next, the operational state of the MCU 10 shown in FIG. 2 for when an anomaly has occurred in the external circuit 20 will be described with reference to FIG. 3.

If an anomalous state occurs in the external circuit 20 as shown in FIG. 3, then the anomaly detection circuit 30 provided outside of the MCU 10 detects the occurrence of the anomaly. The anomaly detection circuit 30, for example, detects a current anomaly, a voltage anomaly, or a temperature anomaly in the external circuit 20, and more specifically, detects overcurrent, overvoltage, abnormal heating, or the like. Upon detecting such anomalies, the anomaly detection circuit 30 outputs the anomaly detection signal 103. Specifically, the anomaly detection circuit 30 sets the anomaly detection signal 103 to a low level.

As a result, the PWM control circuit 14 enters an emergency operation stoppage state, and stops outputting the PWM signal. Also, in the MCU 10 of the present embodiment, as a result of the anomaly detection signal 103 also being inputted to the reset circuit 12, the reset circuit 12 sets the reset signal 104 to a low level indicating active. As a result, the entire MCU 10 is reset and initialized.

As a result of this operation being performed, the entire MCU 10 is reset if some anomaly occurs in the system in which the MCU 10 is used, even if the operation of the software by the CPU 13 is anomalous and the voltage detection circuit 11 cannot detect the anomaly.

### Modification Examples

In the embodiment above, a case was described in which the external circuit 20 includes an IGBT, but the disclosure is not limited thereto, and the disclosure can be similarly applied even to configurations in which the external circuit is controlled by the internal circuit of the MCU 10.

What is claimed is:

1. A microcontroller, comprising:
an internal circuit configured so as to control an operation of an external circuit, and to stop operation and be controlled by a central processing unit (CPU) upon input of an anomaly detection signal from outside;
a voltage detection circuit configured so as to detect a change in a voltage value of a power source voltage and generate and output a hardware reset signal; and
a reset circuit configured to output a reset signal for resetting an entire device if any one of the hardware reset signal from the voltage detection circuit, a software reset signal from the CPU, or the anomaly detection signal becomes active.

2. The microcontroller according to claim 1,
wherein the internal circuit is a pulse width modulation (PWM) control circuit for generating a PWM signal for controlling an operation of an element of the external circuit.

3. An electronic circuit, comprising:
a microcontroller including a CPU;
an external circuit provided outside of the microcontroller; and
an anomaly detection circuit configured to detect an anomalous state in the external circuit and generate an anomaly detection signal,
wherein the microcontroller has:
an internal circuit configured so as to control an operation of the external circuit, and to stop operation and be controlled by the CPU in response to input of the anomaly detection signal from the anomaly detection circuit;
a voltage detection circuit configured so as to detect a change in a voltage value of a power source voltage and generate and output a hardware reset signal; and
a reset circuit configured to output a reset signal for resetting an entire device if any one of the hardware reset signal from the voltage detection circuit, a software reset signal from the CPU, or the anomaly detection signal becomes active.

4. The electronic circuit according to claim 3,
wherein the internal circuit is a PWM control circuit for generating a PWM signal for controlling an operation of an element of the external circuit.

5. The electronic circuit according to claim 3,
wherein, in response to the anomaly detection circuit detecting any one of a current anomaly, a voltage anomaly, or a temperature anomaly in the external circuit, the anomaly detection signal is generated.
